(19) United States
(12) Patent Application Publication
(10) Pub. No.: US 2026/0333889 A1
(43) Pub. Date: Oct. 22, 2026

(54) SEMICONDUCTOR STRUCTURE AND MANUFACTURING METHOD THEREOF

(71) Applicant: United Microelectronics Corp., Hsinchu (TW)

(72) Inventors: Chih Ming Chien, Hsinchu City (TW); Jeng Yu Wang, New Taipei City (TW); Chang-Sheng Hsu, Hsinchu City (TW)

(73) Assignee: United Microelectronics Corp., Hsinchu (TW)

(21) Appl. No.: 19/209,815

(22) Filed: May 16, 2025

(30) Foreign Application Priority Data
Apr. 22, 2025 (TW) 114115073

(51) Int. Cl. H10F 30/223; H10F 71/10; H10F 77/20

(52) U.S. Cl. CPC H10F 30/2235; H10F 71/1035; H10F 77/206

(57) ABSTRACT

Provided are a semiconductor structure and a manufacturing method thereof. The semiconductor structure includes a substrate, a photodiode, a dielectric layer, a first contact, a second contact, an interconnect layer and a barrier layer. The photodiode includes a first doped semiconductor layer in the substrate, a second doped semiconductor layer on the first doped semiconductor layer, and an undoped semiconductor layer therebetween. The dielectric layer covers the photodiode. The first contact is disposed in the dielectric layer, located above and electrically connected to the second doped semiconductor layer. The second contact is disposed in the dielectric layer and electrically connected to the first doped semiconductor layer. The interconnect layer is disposed on the dielectric layer and electrically connected to the first and second contacts. The barrier layer is disposed between the interconnect layer and the dielectric layer. The barrier layer located above the photodiode is discontinuous.

### CROSS-REFERENCE TO RELATED APPLICATION

This application claims the priority benefit of Taiwan application serial no. 114115073, filed on Apr. 22, 2025. The entirety of the above-mentioned patent application is hereby incorporated by reference herein and made a part of this specification.

### BACKGROUND

### Technical Field

The present invention relates to a semiconductor structure and a manufacturing method thereof, and more particularly to a semiconductor structure including a photodiode and a manufacturing method thereof.

### Description of Related Art

In the photoelectric conversion device, the chip including the photodiode may be disposed on the printed circuit board with the back surface of the chip facing the printed circuit board, or may be disposed on the printed circuit board with the front surface of the chip facing the printed circuit board.

For the photoelectric conversion device in which the chip is disposed on the printed circuit board with the front surface of the chip facing the printed circuit board, when light enters from the back surface of the chip, a portion of the light may be directly absorbed by the photodiode, and a portion of the light may pass through the photodiode. The light passing through the photodiode may be reflected by the interconnect layer between the photodiode and the printed circuit board to be absorbed by the photodiode.

However, a barrier layer is usually disposed on the surface of the interconnect layer, and the barrier layer usually has lower light reflectivity compared to the interconnect layer. As a result, when the light passing through the photodiode is reflected by the barrier layer, the reflectivity is low, resulting in poor responsiveness of the photoelectric conversion device.

The present invention provides a semiconductor structure and a manufacturing method thereof, wherein the barrier layer located above the photodiode is discontinuous.

The semiconductor structure of the present invention includes a substrate, a photodiode, a dielectric layer, a first contact, a second contact, an interconnect layer and a barrier layer. The photodiode is disposed at the substrate and includes a first doped semiconductor layer located in the substrate, a second doped semiconductor layer located on the first doped semiconductor layer, and an undoped semiconductor layer located between the first doped semiconductor layer and the second doped semiconductor layer. The first doped semiconductor layer and the second doped semiconductor layer have opposite conductivity types. The dielectric layer is disposed on the substrate and covers the photodiode. The first contact is disposed in the dielectric layer, located above and electrically connected to the second doped semiconductor layer. The second contact is disposed in the dielectric layer and electrically connected to the first doped semiconductor layer. The interconnect layer is disposed on the dielectric layer and electrically connected to the first contact and the second contact. The barrier layer is disposed between the interconnect layer and the dielectric layer. The barrier layer located above the photodiode is discontinuous.

In an embodiment of the semiconductor structure of the present invention, the undoped semiconductor layer includes an undoped germanium layer or an undoped silicon germanium layer.

In an embodiment of the semiconductor structure of the present invention, the first doped semiconductor layer is exposed at a surface of the substrate.

In an embodiment of the semiconductor structure of the present invention, the first doped semiconductor layer is a portion of the substrate.

In an embodiment of the semiconductor structure of the present invention, the second doped semiconductor layer is a doped amorphous silicon layer.

In an embodiment of the semiconductor structure of the present invention, the first barrier layer is located between the second contact and the dielectric layer, between the second contact and the first doped semiconductor layer, between the interconnect layer and the dielectric layer and between the interconnect layer and the first contact, and exposes the dielectric layer directly above the photodiode.

In an embodiment of the semiconductor structure of the present invention, the interconnect layer is in contact with the dielectric layer directly above the photodiode.

In an embodiment of the semiconductor structure of the present invention, the semiconductor structure further includes a second barrier layer disposed between the first contact and the dielectric layer and between the first contact and the second doped semiconductor layer.

In an embodiment of the semiconductor structure of the present invention, a light reflectivity of the interconnect layer is greater than a light reflectivity of the first barrier layer and a light reflectivity of the second barrier layer.

In an embodiment of the semiconductor structure of the present invention, a material of the interconnect layer includes aluminum, and the first barrier layer includes a titanium layer and a titanium nitride layer.

In an embodiment of the semiconductor structure of the present invention, the semiconductor structure further includes third barrier layer disposed on the interconnect layer.

The manufacturing method of the semiconductor structure of the present invention includes the following steps. A substrate is provided. A photodiode is formed at the substrate, wherein the photodiode comprises a first doped semiconductor layer located in the substrate, a second doped semiconductor layer located on the first doped semiconductor layer and an undoped semiconductor layer located between the first doped semiconductor layer and the second doped semiconductor layer, and the first doped semiconductor layer and the second doped semiconductor layer have opposite conductive types. A dielectric layer is formed on the substrate, wherein the dielectric layer covers the photodiode. A first contact is formed in the dielectric layer, wherein the first contact is located above the second doped semiconductor layer and electrically connected to the second doped semiconductor layer. A second contact is formed in the dielectric layer, wherein the second contact is electrically connected to the first doped semiconductor layer. An interconnect layer is formed on the dielectric layer, wherein the interconnect layer is electrically connected to the first contact and the second contact. A first barrier layer is formed between the interconnect layer and the dielectric layer. The first barrier layer located above the photodiode is discontinuous.

In an embodiment of the manufacturing method of the semiconductor structure of the present invention, the first doped semiconductor layer is exposed at a surface of the substrate.

In an embodiment of the manufacturing method of the semiconductor structure of the present invention, a forming method of the first doped semiconductor layer comprises implanting a dopant into the substrate.

In an embodiment of the manufacturing method of the semiconductor structure of the present invention, the first barrier layer is located between the second contact and the dielectric layer, between the second contact and the first doped semiconductor layer, between the interconnect layer and the dielectric layer and between the interconnect layer and the first contact, and exposes the dielectric layer directly above the photodiode.

In an embodiment of the manufacturing method of the semiconductor structure of the present invention, forming methods of the first barrier layer, the second contact layer and the interconnect layer includes the following steps. A contact opening is formed in the dielectric layer, wherein the contact opening exposes the first doped semiconductor layer. A first barrier material layer is conformally formed on the dielectric layer. A portion of the first barrier material layer is removed to expose the dielectric layer directly above the photodiode. A conductive layer is formed on the dielectric layer, wherein the conductive layer fills the contact opening. A patterning process is performed on the conductive layer and the first barrier material layer on a top surface of the dielectric layer to form the interconnect layer on the dielectric layer and to form the second contact in the dielectric layer.

In an embodiment of the manufacturing method of the semiconductor structure of the present invention, a second barrier material layer is further formed on the conductive layer after forming the conductive layer and before performing the patterning process.

In an embodiment of the manufacturing method of the semiconductor structure of the present invention, the first contact is formed before the second contact is formed.

In an embodiment of the manufacturing method of the semiconductor structure of the present invention, a second barrier layer is further formed between the first contact and the dielectric layer and between the first contact and the second doped semiconductor layer.

In an embodiment of the manufacturing method of the semiconductor structure of the present invention, a light reflectivity of the interconnect layer is greater than a light reflectivity of the first barrier layer and a light reflectivity of the second barrier layer.

Based on the above, in the semiconductor structure and manufacturing method thereof of the present invention, the interconnect layer is formed above the photodiode, the barrier layer is formed between the interconnect layer and the photodiode, and the barrier layer above the photodiode is discontinuous. In this way, after light enters from the back surface of the substrate, the light passing through the photodiode may be reflected by the interconnect layer with relatively high light reflectivity instead of being reflected by the barrier layer with relatively low light reflectivity.

### BRIEF DESCRIPTION OF THE DRAWINGS

FIGS. 1A-1F are schematic cross-sectional views of the manufacturing process of the semiconductor structure of the embodiment of the present invention.

### DESCRIPTION OF THE EMBODIMENTS

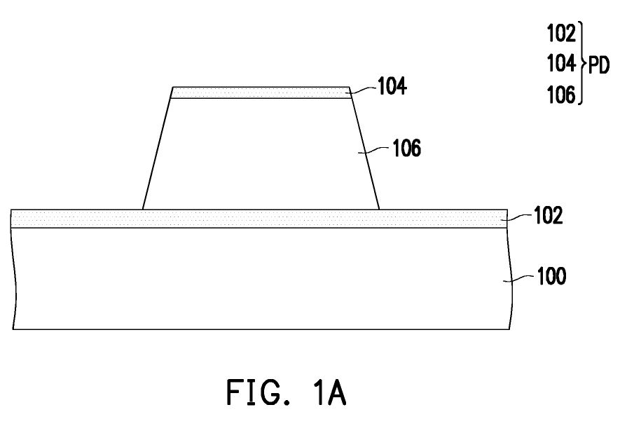

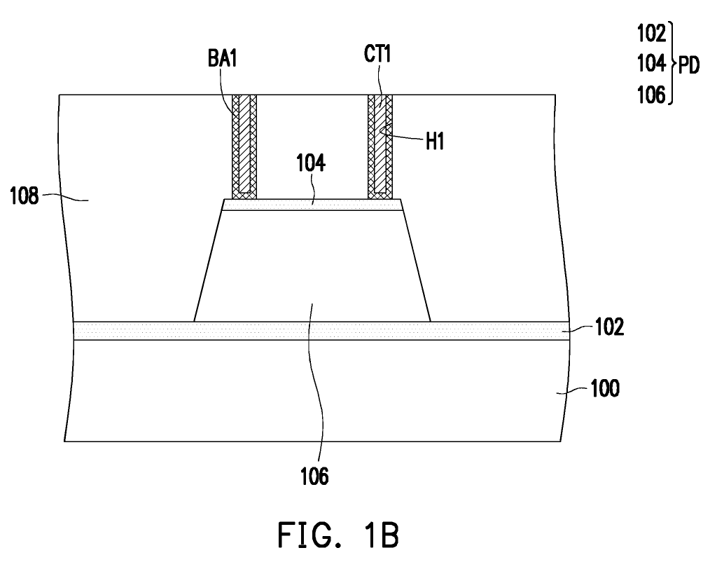

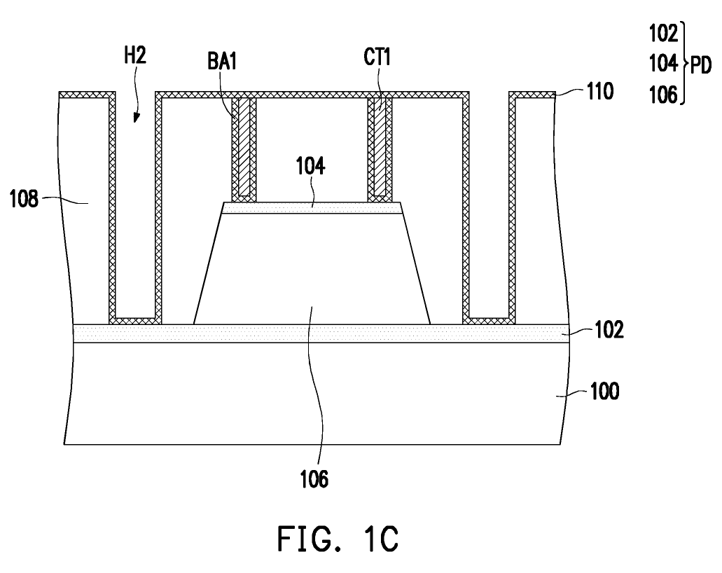

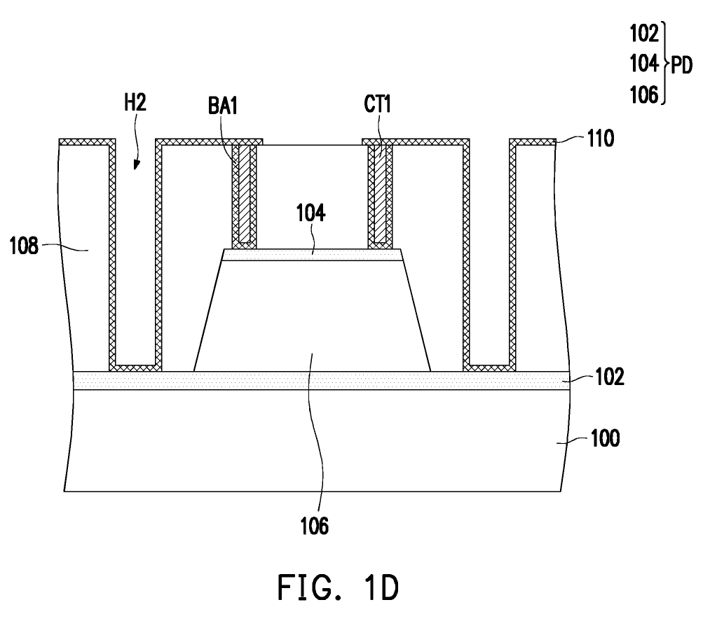

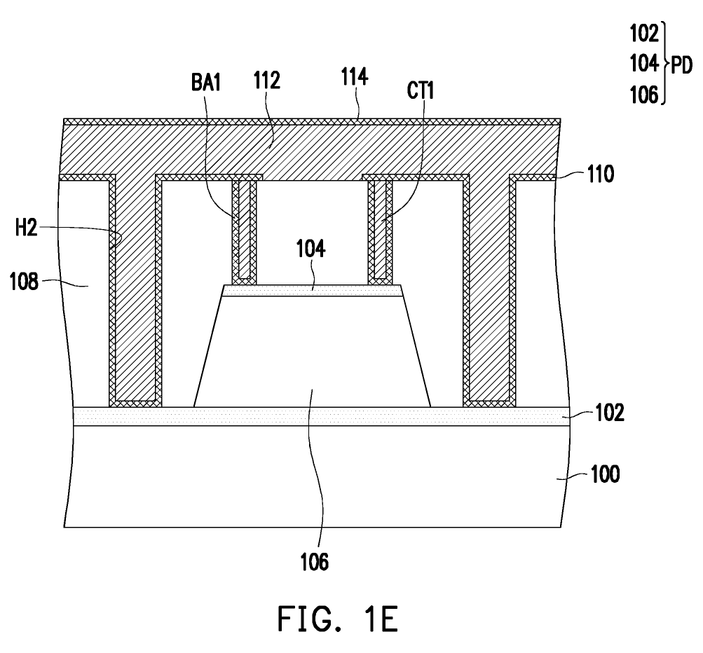

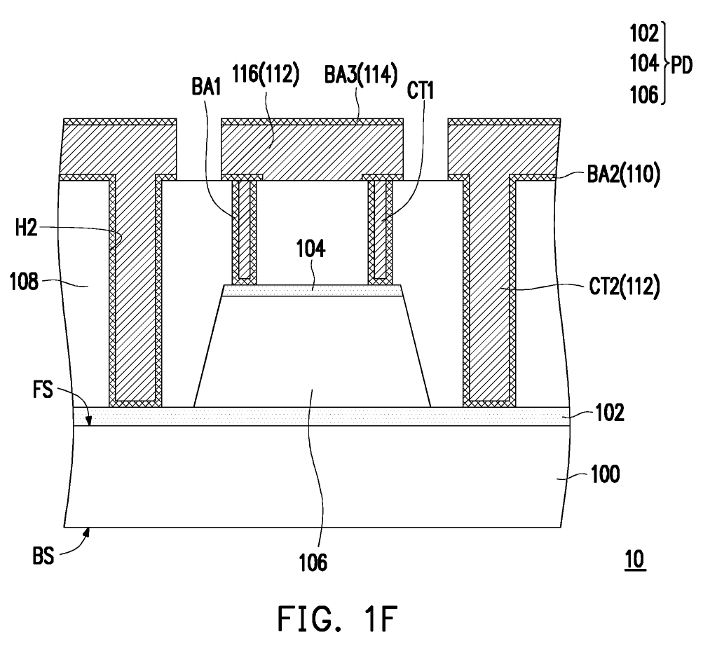

FIGS. 1A-1F are schematic cross-sectional views of the manufacturing process of the semiconductor structure of the embodiment of the present invention.

Referring to FIG. 1A, a substrate 100 is provided. In the present embodiment, the substrate 100 may be a silicon substrate or a silicon-on-insulator (SOI) substrate. Next, a photodiode PD is formed on the substrate 100. In the present embodiment, the photodiode PD includes a doped semiconductor layer 102 located in the substrate 100, a doped semiconductor layer 104 located on the doped semiconductor layer 102, and an undoped semiconductor layer 106 located between the doped semiconductor layer 102 and the doped semiconductor layer 104. The doped semiconductor layer 102 and the doped semiconductor layer 104 have opposite conductive types. The conductive type of the doped semiconductor layer 102 may be one of the P-type and the N-type, and the conductive type of the doped semiconductor layer 104 may be the other of the P-type and the N-type.

In the present embodiment, the conductive type of the doped semiconductor layer 102 may be the P-type, the conductive type of the doped semiconductor layer 104 may be the N-type, and the undoped semiconductor layer 106 is located between the doped semiconductor layer 102 and the doped semiconductor layer 104. Therefore, the photodiode PD is a PIN diode.

In the present embodiment, the doped semiconductor layer 102 is formed by, for example, implanting the dopant into a portion of the substrate 100 adjacent to the top surface of the substrate 100. Therefore, the doped semiconductor layer 102 is exposed at the surface of the substrate 100, and may be regarded as a portion of the substrate 100. In addition, the doped semiconductor layer 104 may be a doped amorphous silicon layer, and the undoped semiconductor layer 106 may be an undoped germanium (Ge) layer or an undoped silicon germanium (SiGe) layer. The forming method and the configuration of the photodiode PD are well known to those skilled in the art and will not be described here.

Referring to FIG. 1B, a dielectric layer 108 is formed on the substrate 100. The dielectric layer 108 covers the photodiode PD. The dielectric layer 108 is, for example, a silicon oxide layer. Then, contacts CT1 are formed in the dielectric layer 108, and a barrier layer BA1 is formed between the contacts CT1 and the dielectric layer 108 and between the contacts CT1 and the doped semiconductor layer 104 of the photodiode PD.

In the present embodiment, the forming method of the contacts CT1 and the barrier layer BA1 may include the following steps. First, contact openings H1 are formed in the dielectric layer 108. The contact opening H1 exposes the doped semiconductor layer 104. Next, a barrier material layer is conformally formed on the dielectric layer 108. The barrier material layer is composed of, for example, a titanium (Ti) layer and a titanium nitride (TiN) layer, but the present invention is not limited thereto. Then, a conductive layer is formed on the barrier material layer. The conductive layer fills the contact openings H1. The conductive layer is, for example, a tungsten (W) layer, but the present invention is not limited thereto. Afterwards, the conductive layer and the barrier material layer outside the contact openings H1 are removed. In this way, the conductive layer and the barrier material layer in the contact openings H1 respectively form the contacts CT1 and the barrier layer BA1 surrounding the sidewalls and the bottoms of the contacts CT1. In addition, the contacts CT1 are located above the doped semiconductor layer 104 of the photodiode PD, and are electrically connected to the doped semiconductor layer 104.

In FIG. 1B, two contacts CT1 are shown, and the contacts CT1 are located at the edge of the doped semiconductor layer 104, but the present invention is not limited thereto. In other embodiments, the number and the positions of the contacts CT1 may be adjusted according to actual needs.

Referring to FIG. 1C, contact openings H2 are formed in the dielectric layer 108. The contact openings H2 are located around the doped semiconductor layer 104 and the undoped semiconductor layer 106, and expose the doped semiconductor layer 102. In FIG. 1C, two contact openings H2 are shown, but the present invention is not limited thereto. In other embodiments, the number of the contact openings H2 may be adjusted according to actual needs.

After forming the contact openings H2, a barrier material layer 110 is conformally formed on the dielectric layer 108. The barrier material layer 110 covers the top surface of the dielectric layer 108, the top surfaces of the contacts CT1, the top surface of the barrier layer BA1, the sidewalls of the contact openings H2, and the doped semiconductor layer 102 exposed by the contact openings H2. The barrier material layer 110 is composed of, for example, a Ti layer and a TiN layer, but the present invention is not limited thereto.

Referring to FIG. 1D, a portion of the barrier material layer 110 is removed to expose the dielectric layer 108 above the photodiode PD. In the present embodiment, after removing a portion of the barrier material layer 110, the dielectric layer 108 directly above the photodiode PD is exposed.

For example, a patterned mask layer (not shown) is formed on the barrier material layer 110. The patterned mask layer exposes a region directly above the photodiode PD. In the present embodiment, the patterned mask layer exposes the region directly above the center portion of the photodiode PD. An etching process is performed using the patterned mask layer as the etching mask to remove the exposed barrier material layer 110. The patterned mask layer is removed. In this way, the remaining barrier material layer 110 exposes the dielectric layer 108 directly above the photodiode PD. In the present embodiment, the remaining barrier material layer 110 exposes the dielectric layer 108 directly above the center portion of the photodiode PD.

Referring to FIG. 1E, a conductive layer 112 is formed on the dielectric layer 108. The conductive layer 112 covers the barrier material layer 110 and fills the contact openings H2. In the present embodiment, the conductive layer 112 is an aluminum (Al) layer, but the present invention is not limited thereto, as long as the light reflectivity of the conductive layer 112 is greater than the light reflectivity of the barrier material layer 110.

Furthermore, in the present embodiment, since the barrier material layer 110 exposes the dielectric layer 108 above the photodiode PD, the conductive layer 112 may be in contact with the dielectric layer 108 above the photodiode PD. In the present embodiment, the conductive layer 112 is in contact with the dielectric layer 108 directly above the center portion of the photodiode PD.

After forming the conductive layer 112, a barrier material layer 114 may be formed on the conductive layer 112. In the present embodiment, the barrier material layer 114 may be a TiN layer, but the present invention is not limited thereto.

Referring to FIG. 1F, a patterning process is performed on the barrier material layer 114, the conductive layer 112 and the barrier material layer 110 on the top surface of the dielectric layer 108 to form an interconnect layer 116 on the dielectric layer 110 and a barrier layer BA3 on the interconnect layer 116, and to form contacts CT2 in the dielectric layer 108. The interconnect layer 110 may be electrically connected to the contacts CT1 and the contacts CT2, respectively.

In detail, after the patterning process, the conductive layer 112 remaining in the contact openings H2 constitutes the contacts CT2, and the conductive layer 112 remaining on the top surface of the dielectric layer 108 constitutes the interconnect layer 116. In addition, a portion of the interconnect layer 116 may be located over the contacts CT2 to be connected to the contacts CT2, and a portion of the interconnect layer 116 may be located over the photodiode PD to be electrically connected to the contacts CT1. The barrier material layer 114 located on the interconnect layer 116 constitutes a barrier layer BA3.

In addition, the barrier material layer 110 remaining between the contacts CT2 and the dielectric layer 108, between the contacts CT2 and the doped semiconductor layer 102, between the interconnect layer 116 and the dielectric layer 108, between the interconnect layer 116 and the barrier layer BA1 and between the interconnect layer 116 and the contacts C1 constitutes a barrier layer BA2. Therefore, the barrier layer BA2 exposes the dielectric layer 108 above the photodiode PD. In the present embodiment, the barrier layer BA2 exposes the dielectric layer 108 directly above the center portion of the photodiode PD. In other words, the barrier layer BA2 located above the photodiode PD is discontinuous.

In this way, a semiconductor structure 10 including the photodiode PD of the present embodiment is formed. In the semiconductor structure 10, the interconnect layer 116 is located above the photodiode PD, the barrier layer BA2 is located between the interconnect layer 116 and the photodiode PD, and the barrier layer BA2 above the photodiode PD is discontinuous. In particular, the barrier layer BA2 directly above the photodiode PD is discontinuous.

When light enters from the back surface BS of the substrate 100, a portion of the light is directly absorbed by the photodiode PD, and a portion of the light passes through the photodiode PD and is reflected by the interconnect layer 116 and then absorbed by the photodiode PD. Since the barrier layer BA2 above the photodiode PD is discontinuous, the light passing through the photodiode PD may be reflected by the interconnect layer 116 having a relatively high light reflectivity, rather than being reflected by the barrier layer BA2 having a relatively low light reflectivity. Therefore, when the semiconductor structure 10 is disposed on a printed circuit board (not shown) with the front surface FS facing the printed circuit board to form a photoelectric conversion device, the photoelectric conversion device may have a better response rate.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate;
a photodiode, disposed at the substrate, and comprising a first doped semiconductor layer located in the substrate, a second doped semiconductor layer located on the first doped semiconductor layer and an undoped semiconductor layer located between the first doped semiconductor layer and the second doped semiconductor layer, wherein the first doped semiconductor layer and the second doped semiconductor layer have opposite conductive types;
a dielectric layer, disposed on the substrate and covering the photodiode;
a first contact, disposed in the dielectric layer, located above the second doped semiconductor layer, and electrically connected to the second doped semiconductor layer;
a second contact, disposed in the dielectric layer, and electrically connected to the first doped semiconductor layer;
an interconnect layer, disposed on the dielectric layer, and electrically connected to the first contact and the second contact; and
a first barrier layer, disposed between the interconnect layer and the dielectric layer,
wherein the first barrier layer located above the photodiode is discontinuous.

2. The semiconductor structure of claim 1, wherein the undoped semiconductor layer comprises an undoped germanium layer or an undoped silicon germanium layer.

3. The semiconductor structure of claim 1, wherein the first doped semiconductor layer is exposed at a surface of the substrate.

4. The semiconductor structure of claim 3, wherein the first doped semiconductor layer is a portion of the substrate.

5. The semiconductor structure of claim 1, wherein the second doped semiconductor layer is a doped amorphous silicon layer.

6. The semiconductor structure of claim 1, wherein the first barrier layer is located between the second contact and the dielectric layer, between the second contact and the first doped semiconductor layer, between the interconnect layer and the dielectric layer and between the interconnect layer and the first contact, and exposes the dielectric layer directly above the photodiode.

7. The semiconductor structure of claim 6, wherein the interconnect layer is in contact with the dielectric layer directly above the photodiode.

8. The semiconductor structure of claim 1, further comprising a second barrier layer disposed between the first contact and the dielectric layer and between the first contact and the second doped semiconductor layer.

9. The semiconductor structure of claim 8, wherein a light reflectivity of the interconnect layer is greater than a light reflectivity of the first barrier layer and a light reflectivity of the second barrier layer.

10. The semiconductor structure of claim 9, wherein a material of the interconnect layer comprises aluminum, and the first barrier layer comprises a titanium layer and a titanium nitride layer.

11. The semiconductor structure of claim 1, further comprising a third barrier layer disposed on the interconnect layer.

12. A manufacturing method of a semiconductor structure, comprising:
providing a substrate;
forming a photodiode at the substrate, wherein the photodiode comprises a first doped semiconductor layer located in the substrate, a second doped semiconductor layer located on the first doped semiconductor layer and an undoped semiconductor layer located between the first doped semiconductor layer and the second doped semiconductor layer, and the first doped semiconductor layer and the second doped semiconductor layer have opposite conductive types;
forming a dielectric layer on the substrate, wherein the dielectric layer covers the photodiode;
forming a first contact in the dielectric layer, wherein the first contact is located above the second doped semiconductor layer and electrically connected to the second doped semiconductor layer;
forming a second contact in the dielectric layer, wherein the second contact is electrically connected to the first doped semiconductor layer;
forming an interconnect layer on the dielectric layer, wherein the interconnect layer is electrically connected to the first contact and the second contact; and
forming a first barrier layer between the interconnect layer and the dielectric layer,
wherein the first barrier layer located above the photodiode is discontinuous.

13. The manufacturing method of claim 12, wherein the first doped semiconductor layer is exposed at a surface of the substrate.

14. The manufacturing method of claim 13, wherein a forming method of the first doped semiconductor layer comprises implanting a dopant into the substrate.

15. The manufacturing method of claim 12, wherein the first barrier layer is located between the second contact and the dielectric layer, between the second contact and the first doped semiconductor layer, between the interconnect layer and the dielectric layer and between the interconnect layer and the first contact, and exposes the dielectric layer directly above the photodiode.

16. The manufacturing method of claim 15, wherein forming methods of the first barrier layer, the second contact layer and the interconnect layer comprises:
forming a contact opening in the dielectric layer, wherein the contact opening exposes the first doped semiconductor layer;
conformally forming a first barrier material layer on the dielectric layer;
removing a portion of the first barrier material layer to expose the dielectric layer directly above the photodiode;
forming a conductive layer on the dielectric layer, wherein the conductive layer fills the contact opening; and
performing a patterning process on the conductive layer and the first barrier material layer on a top surface of the dielectric layer to form the interconnect layer on the dielectric layer and to form the second contact in the dielectric layer.

17. The manufacturing method of claim 16, further comprising forming a second barrier material layer on the conductive layer after forming the conductive layer and before performing the patterning process.

18. The manufacturing method of claim 12, wherein the first contact is formed before the second contact is formed.

19. The manufacturing method of claim 12, further comprising forming a second barrier layer between the first contact and the dielectric layer and between the first contact and the second doped semiconductor layer.

20. The manufacturing method of claim 19, wherein a light reflectivity of the interconnect layer is greater than a light reflectivity of the first barrier layer and a light reflectivity of the second barrier layer.
